(19) United States
(12) Patent Application Publication
(10) Pub. No.: US 2008/0057442 A1
(43) Pub. Date: Mar. 6, 2008

(54) Method and apparatus for manufacturing band stop filter

(75) Inventor: Sang June Kim, Seoul (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBU HITEK CO., LTD.

(21) Appl. No.: 11/892,397

(22) Filed: Aug. 22, 2007

(30) Foreign Application Priority Data
Sep. 6, 2006 (KR) 10-2006-0085487

(51) Int. Cl. G03F 7/20; H01S 3/08

(52) U.S. Cl. 430/321; 372/101

(57) ABSTRACT

A method and an apparatus for manufacturing a band stop filter are disclosed. In one aspect, the method uses hologram lithography to produce the band stop filter of a smaller size without the need of a mask.

This application claims the benefit of priority from Korean Patent Application No. 10-2006-0085487, filed on Sep. 6, 2006, the entire contents of which are incorporated herein by reference.

### BACKGROUND

1. Technical Field

The present invention relates generally to a method and an apparatus for manufacturing a band stop filter, and more particularly, to a method and an apparatus for manufacturing a band stop filter capable of fabricating a pattern using a hologram lithography and a photolithography.

2. Related Art

Generally, a lithography process in the semiconductor industry refers to a process for transcribing patterns. The lithography process is important in the fabrication of integrated circuits (IC). The lithography process may be classified into an optical lithography based on light, an electron-beam lithography based on electron beams, and an X-ray lithography based on X-rays.

Optical lithography technology may employ ultraviolet (UV) rays as the light source. Generally, optical lithography technology uses a photo mask for selectively transmitting light to transfer a pattern.

The light that penetrates the photo mask arrives at a photoresist, forms a latent image on the photoresist, and forms a photoresist pattern, which is caused to form a semiconductor device having a desired pattern by an etching process based on the photo mask.

A variety of Resolution Enhancement Techniques (RET) have been used to pattern circuit features of lengths shorter than the wavelength of the light source. For example, the RET may be a transform illumination system and/or a phase inversion mask.

In addition, a conventional band stop filter has been implemented by passive components, i.e., a resistor (R), an inductor (L), and a capacitor (C). When the passive components are used, individual components may occupy a very large area on a chip. Accordingly, it may be difficult to reduce the chip size when implementing a System-On-Chip (SOC) architecture.

### SUMMARY

Accordingly, the present invention is directed to a method and an apparatus for manufacturing a band stop filter (BSF) that may obviate one or more disadvantages in the related art.

The present invention provides a BSF fabrication method that produces a pattern using a hologram lithography and a photolithography, thereby reducing the chip size.

In one aspect, there is provided a method for manufacturing a band stop filter, which includes: coating a photosensitive material on a metal or dielectric substance; performing a first lithography process on the metal or dielectric substance coated with the photosensitive material, in a predetermined oblique direction using a hologram lithography to form a plurality of first oblique lines; rotating the metal or dielectric substance by about 180 degrees, and performing a second lithography process on the rotated metal or dielectric substance in the predetermined oblique direction using the hologram lithography to form a plurality of second oblique lines; performing a third lithography on the metal or dielectric substance to form a desired pattern; and forming the band stop filter including passive components by an etching process or a metal etching process.

In one embodiment, the hologram lithography is able to change a period of a desired pattern, a period interval, a pattern radius, and a pattern shape using constructive and destructive interference of light.

In one embodiment, the photosensitive material may comprise different reflection coefficients according to a desired properties of the band stop filter.

In another aspect, there is provided an apparatus for manufacturing a band stop filter. The apparatus includes: a laser illuminator for generating a laser beam; a shutter disposed on the same axis as that of the laser illuminator to transmit or block the laser beam from the laser illuminator; a first mirror having an incident plane disposed on the same axis as that of the shutter, the first mirror reflecting the laser beam from the shutter and transmitting the reflected laser beam via an exit plane; a beam-extending lens disposed on the same axis as that of the first mirror to extend the laser beam from the first mirror; a slit disposed on the same axis as that of the beam-extending lens to split the laser beam from the beam-extending lens; a collimating lens having an incident plane disposed on the same axis as that of the slit to convert the laser beam split by the slit into parallel laser beams; a second mirror including an incident plane disposed on the same axis as that of the collimating lens to reflect the laser beam from the collimating lens and to transmit the reflected laser beam to a metal or dielectric substance via an exit plane; and a controller for varying a period of a desired pattern, a period interval, a pattern radius, and a pattern shape using constructive and destructive interference of the laser beams by controlling the laser illuminator and the shutter.

In one embodiment, the metal or dielectric substance is disposed on a wafer chuck, and the wafer chuck is rotatable by about 180 degrees.

It is to be understood that both the foregoing general description and the following detailed description consistent with the present invention are exemplary and explanatory, and are intended to provide further explanation of the invention as claimed.

### BRIEF DESCRIPTION OF THE DRAWINGS

In the drawings:

FIG. 1 illustrates a band diagram of a photonic crystal of a two-dimensional (2D) triangular lattice, including a photonic bandgap, according to an embodiment consistent with the present invention;

FIG. 2 illustrates an apparatus for manufacturing a band stop filter according to an embodiment consistent with the present invention;

FIG. 3 illustrates a band stop filter fabricated using a method for manufacturing the band stop filter according to an embodiment consistent with the present invention; and

FIG. 4 illustrates the operation of the band stop filter according to an embodiment consistent with the present invention.

### DETAILED DESCRIPTION

Reference will now be made in detail to embodiments consistent with the present invention, examples of which are illustrated in the accompanying drawings. Wherever possible, the same reference numerals will be used to refer to the same or like parts.

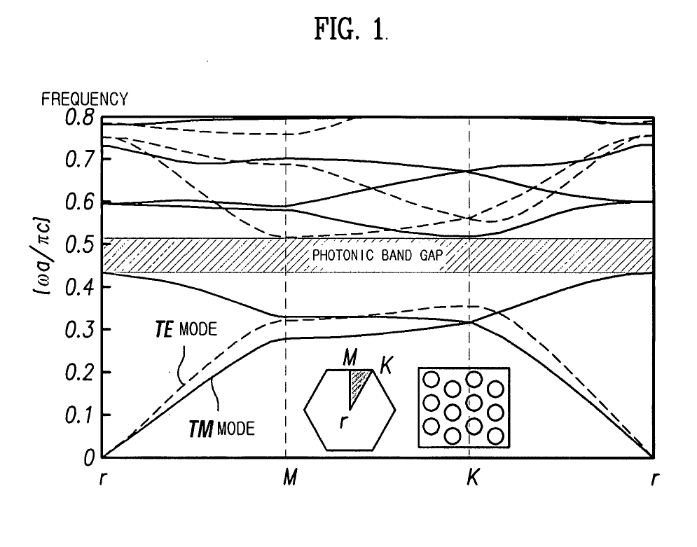

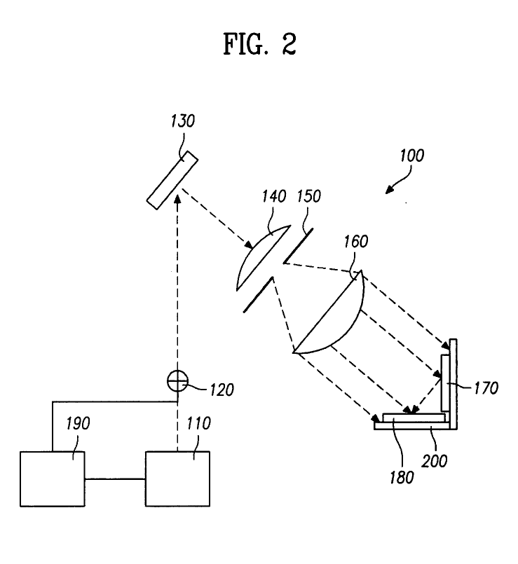

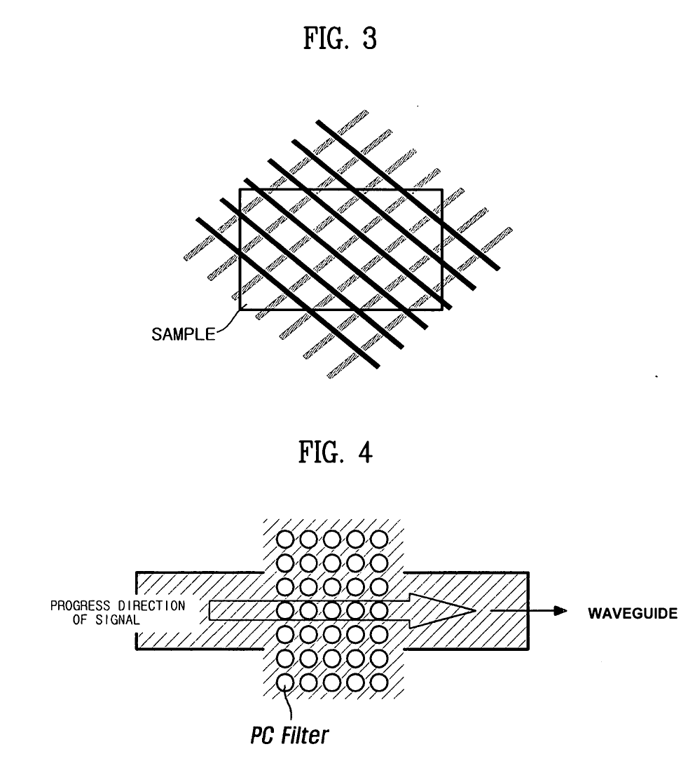

FIG. 1 illustrates a forbidden band of a photonic crystal of a two-dimensional (2D) triangular lattice according to an embodiment consistent with the present invention. FIG. 2 illustrates an apparatus for manufacturing a band stop filter according to an embodiment consistent with the present invention. FIG. 3 illustrates a band stop filter fabricated according to an embodiment consistent with the present invention. FIG. 4 illustrates the operations of the band stop filter according to an embodiment consistent with the present invention.

An apparatus 100 (i.e., a hologram lithography) for manufacturing a band stop filter consistent with the present invention will be described with reference to FIG. 2.

Referring to FIG. 2, apparatus 100 may include: a laser illuminator 110 for creating/illuminating a laser beam; a shutter 120, which may be installed on the same axis as that of laser illuminator 110 to transmit and/or block the laser beam (the laser beam path being drawn by dashed arrows in FIG. 2) of laser illuminator 110; a first mirror 130 having an incident plane, which may be installed on the same axis as that of shutter 120 to reflect the laser beam illuminated via shutter 120, and to transmit the reflected laser beam via an exit plane; a beam-extending lens 140, which may be installed on the same axis as that of first mirror 130 to extend the laser beam illuminated via first mirror 130; a slit 150, which may be installed on the same axis as that of beam-extending lens 140 to split the laser beam illuminated via beam-extending lens 140; a collimating lens 160, which may be installed on the same axis as that of slit 150 to convert the laser beam split by slit 150 into a parallel laser beam; and a second mirror 170 having an incident plane installed on the same axis as that of collimating lens 160 to reflect the laser beam illuminated via collimating lens 160, and to transmit the reflected laser beam to a metal or dielectric substance 180 via an exit plane.

Still referring to FIG. 2, laser illuminator 110 and shutter 120 may be controlled by a controller 190. Upon receiving a control signal from controller 190, laser illuminator 110 and shutter 120 may change a desirable pattern period, a period interval, a pattern radius, and a pattern shape using constructive and/or destructive interference of the laser beam.

A wafer chuck 200, on which metal or dielectric substance 180 is placed, may rotate by 180°. Second mirror 170 is fixed to a lateral side of wafer chuck 200.

A method for manufacturing a band stop filter consistent with the present invention will be described with reference to FIGS. 1 to 4.

All crystals, including semiconductor crystals, are composed of periodic arrangements of atoms or molecules. One may model such periodic arrangements as a periodic electrostatic potential. The periodic electrostatic potential forms an energy area, in which electrons are forbidden. This energy area is called an electronic band gap.

Similar to the above-mentioned electronic band gap, a periodic arrangement of different dielectric substances may constitute an electromagnetic or photonic band gap.

Referring to FIG. 1, which illustrates a band diagram of a photonic crystal, the photonic band gap of a 2D triangular-lattice photonic-crystal may be a forbidden band represented by a shaded area. The forbidden band has a unique property that no light of frequency within the forbidden band is allowed to pass through the photonic crystal. The forbidden band may be altered according to the type of photonic crystal structure (e.g., hexagon or rectangle), the periodicity of the photonic crystal, the radius of a pattern that forms the photonic crystal, the reflection coefficient of the material of the pattern, and the shape of the pattern (e.g., oval or other shapes).

Referring to FIG. 2, a photosensitive material may be coated on metal or dielectric substance 180 using the above-mentioned property. Referring to FIG. 3, a primary lithography process may be performed on metal or dielectric substance 180 coated with the photosensitive material, in a predetermined oblique direction, using hologram lithography 100 (shown in FIG. 2) to form a plurality of first oblique lines. Then, a secondary lithography process may be performed, using hologram lithography 100 (shown in FIG. 2), in the predetermined oblique direction after rotating metal or dielectric substance 180 by about 180 degrees, so as to form a plurality of second oblique lines. Then, a third lithography process is performed on the metal or dielectric substance using a photolithography process, thereby forming a pattern on the metal or dielectric substance, as shown in FIG. 3. The aforementioned oblique direction may be set to about 45 degrees. Each of the first and second oblique lines may have a constant thickness. The first and second oblique lines may be spaced apart from each other at a predetermined distance.

Thereafter, a band stop filter may be manufactured, including passive components formed by an etching process or a metal etching process.

In one embodiment, the lithography process performed in hologram lithography 100 employs the constructive and destructive interference of light. Accordingly, there is no need to manufacture an additional mask. In addition, the aforementioned lithography process may freely adjust the period of a desired pattern and/or the pattern radius. The photosensitive material may be selected to have different reflection coefficients according to the desired properties of the band stop filter. Therefore, by properly selecting the reflection coefficient of the photosensitive material and the above-mentioned parameters, i.e., the type of photonic crystal structure (e.g., hexagon or rectangle), the periodicity of the photonic crystal, the radius of a pattern that forms the photonic crystal, the reflection coefficient of the material of the pattern, and the shape of the pattern (e.g., oval or other shapes), the band stop filter may block a desired frequency.

The band stop filter consistent with the present invention occupies an area smaller than that of a passive filter composed of a resistor (R), an inductor (L), and a capacitor (C). As a result, if the band stop filter is applied to the SOC, the occupied area is reduced significantly.

As shown in FIG. 4, if a signal passes through a filter structure (i.e., the band stop filter shown in FIG. 3), the band stop filter may block signals of a specific frequency range conforming with the photonic band gap shown in FIG. 1.

As apparent from the above description, the method for manufacturing the band stop filter consistent with the present invention provides a smaller-sized band stop filter, and may block signals of a desired frequency band in various ways without using a mask, because it uses hologram lithography.

It will be apparent to those skilled in the art that various modifications and variations can be made in view of the present invention without departing from the spirit and/or scope of the invention. Thus, it is intended that the present invention covers the various modifications and variations that fall within the scope of the appended claims and their equivalents.

What is claimed is:

1. A method for manufacturing a band stop filter comprising:
coating a photosensitive material on a metal or dielectric substance;
performing a first lithography process on the metal or dielectric substance coated with the photosensitive material in a predetermined oblique direction using a hologram lithography to form a plurality of first oblique lines;
rotating the metal or dielectric substance by about 180 degrees, and performing a second lithography process on the rotated metal or dielectric substance in the predetermined oblique direction using the hologram lithography to form a plurality of second oblique lines;
performing a third lithography process on the metal or dielectric substance to form a desired pattern on the metal or dielectric substance; and
forming the band stop filter including passive components by an etching process or a metal etching process.

2. The method according to claim 1, further comprising varying a period of the desired pattern, a period interval, a pattern radius, and a pattern shape using constructive and destructive interference of light.

3. The method according to claim 1, wherein the photosensitive material comprises a material having a reflection coefficient corresponding to a desired property of the band stop filter.

4. The method according to claim 2, wherein the photosensitive material comprises a material having reflection coefficient corresponding to a desired property of the band stop filter.

5. The method according to claim 1, wherein the predetermined oblique direction is about 45 degrees.

6. The method according to claim 1, wherein each of the first and second oblique lines has a constant thickness.

7. The method according to claim 1, wherein the first and second oblique lines are spaced apart from each other at a predetermined distance.

8. An apparatus for manufacturing a band stop filter comprising:
a laser illuminator for generating a laser beam;
a shutter disposed on the same axis as that of the laser illuminator to transmit or block the laser beam from the laser illuminator;
a first mirror having an incident plane on the same axis as that of the shutter, the first mirror reflecting the laser beam illuminated from the shutter and transmitting the reflected laser beam via an exit plane;
a beam-extending lens disposed on the same axis as that of the first mirror to extend the laser beam from the first mirror;
a slit disposed on the same axis as that of the beam-extending lens to split the laser beam from the beam-extending lens;
a collimating lens having an incident plane disposed on the same axis as that of the slit to convert the laser beam split by the slit into parallel laser beams;
a second mirror having an incident plane disposed on the same axis as that of the collimating lens to reflect the laser beam illuminated from the collimating lens and transmit the reflected laser beam to a metal or dielectric substance via an exit plane; and
a controller for varying a period of a desired pattern, a period interval, a pattern radius, and a pattern shape using constructive and destructive interference of the laser beams by controlling the laser illuminator and the shutter.

9. The apparatus according to claim 8, wherein the metal or dielectric substance is disposed on a wafer chuck, and the wafer chuck is rotatable by about 180 degrees.
